(19) United States
(12) Patent Application Publication
(10) Pub. No.: US 2026/0239638 A1
(43) Pub. Date: Aug. 13, 2026

(54) METHOD FOR MANUFACTURING SEMICONDUCTOR DEVICE AND MESA DIODE

(71) Applicant: SHINDENGEN ELECTRIC MANUFACTURING CO., LTD., Chiyoda-ku, Tokyo (JP)

(72) Inventors: Atsushi OGASAWARA, Asaka City, Saitama (JP); Koji ITO, Asaka City, Saitama (JP); Ryota MURAI, Asaka City, Saitama (JP)

(21) Appl. No.: 19/135,845

(22) PCT Filed: Aug. 5, 2024
(86) PCT No.: PCT/JP2024/080136

§ 371 Date: Jun. 5, 2025

(30) Foreign Application Priority Data
Dec. 21, 2023 (JP) 2023-215711

(51) Int. Cl. H10D 8/00; H10D 8/01; H10D 62/83; H10P 14/60; H10P 14/692; H10P 50/64; H10P 54/40

(52) U.S. Cl. CPC H10D 8/422; H10D 8/045; H10D 62/83; H10P 14/6346; H10P 14/69215; H10P 50/642; H10P 54/40

(57) ABSTRACT

A method for manufacturing a semiconductor device using lead-free glass without using a photolithography step and a large amount of chemicals is provided. Insulating films are formed on an upper surface and lower surface of a silicone wafer having a PN junction. A groove is formed in the upper surface having a depth exceeding the PN junction. The inner surface of the groove is wet-etched to reduce a surface roughness and a silicon oxide film is formed on the inner surface of the groove. A lead-free glass layer is formed on the silicon oxide film and the insulating films are removed. Metal films are formed on the upper surface and the lower surface of the silicon wafer. The lead-free glass layer and the silicon wafer are cut along a center of a bottom surface of the groove.

### TECHNICAL FIELD

The present invention relates to a method for manufacturing a semiconductor device and a mesa diode.

### BACKGROUND ART

A method for manufacturing a mesa diode using glass passivation according to the related art has a step of forming a groove in a silicon wafer. In this step, an insulating film is formed on an upper surface of the silicon wafer having a PN junction, a photoresist film is formed on the insulating film, the photoresist film is exposed and developed to form a resist pattern, the insulating film is etched using the resist pattern as a mask, and then wet etching is performed to form a groove with a depth exceeding the PN junction. The step of forming the groove in the silicon wafer in this way has a photolithography step or a step of using a large amount of chemicals at the time of the wet etching. Therefore, costs tend to increase. A technique related to this is disclosed in Patent Document 1.

In addition, it is necessary to respond to regulations on lead in glass by the European RoHS regulation.

Therefore, there is a demand for a mesa diode that can be manufactured using lead-free glass without using the photolithography step and a large amount of chemicals.

### CITATION LIST

### Patent Document

Patent Document 1: WO2014/155739

### SUMMARY OF THE INVENTION

### Problem to be Solved by the Invention

An object of various aspects of the invention is to provide a mesa diode manufactured using lead-free glass without using a photolithography step and a large amount of chemicals and a method for manufacturing a semiconductor device.

### Means for Solving Problem

Various aspects of the invention will be described below. There is provided a method for manufacturing a semiconductor device including:
a step (a) of forming insulating films on upper and lower surfaces of a silicon wafer having a PN junction;
a step (b) of cutting the upper surface of the silicon wafer with a dicing blade to form a groove with a depth exceeding the PN junction;
a step (c) of wet-etching an inner surface of the groove to reduce a surface roughness of the inner surface of the groove to 0.1 μm or less;
a step (d) of forming a silicon oxide film on the inner surface of the groove;
a step (e) of forming a lead-free glass layer on the silicon oxide film on the inner surface of the groove;
a step (f) of removing the insulating films;
a step (g) of forming metal films on the upper and lower surfaces of the silicon wafer; and
a step (h) of cutting the lead-free glass layer and the silicon wafer along a center of a bottom surface of the groove.

In the method for manufacturing a semiconductor device described above according to aspect of the invention, when the upper surface of the silicon wafer having the PN junction is cut with the dicing blade to form the groove having the depth exceeding the PN junction, the inner surface of the groove becomes a rough surface having irregularities. Therefore, in the step (c), the inner surface of the groove is wet-etched to reduce the surface roughness of the inner surface of the groove to 0.1 μm or less. Then, the silicon oxide film is formed on the inner surface of the groove, and the lead-free glass layer as a passivation is formed on the silicon oxide film on the inner surface of the groove. The use of the lead-free glass layer and cutting with the dicing blade makes it possible to manufacture a semiconductor device without using a photolithography step or a large amount of chemicals. In addition, since the lead-free glass layer reduces the surface roughness of the inner surface of the groove to 0.1 μm or less, the semiconductor device can have high withstand voltage characteristics.

In the method for manufacturing a semiconductor device described above, the silicon oxide film formed in the step (d) is an oxide film having a thickness of 100 nm or less.

According to the method for manufacturing a semiconductor device described above according to an aspect of the invention, since the silicon oxide film is an oxide film having a thickness of 100 nm or less, the lead-free glass can be formed by an electrophoretic deposition method.

In the method for manufacturing a semiconductor device described above, an angle formed between the bottom surface and a side surface of the groove in a cross section of the groove formed in the step (b) is equal to or greater than 60° and equal to or less than 90° (preferably equal to or greater than 76° and equal to or less than) 90°.

According to the method for manufacturing a semiconductor device described above according to an aspect of the invention, the angle formed between the bottom surface and the side surface of the groove in the cross section of the groove formed in the step (b) is equal to or greater than 60° and equal to or less than 90° (preferably equal to or greater than 76° and equal to or less than 90°). When the angle is 90° or close to 90° as described above, it is not necessary to perform bevel cutting with the dicing blade, or only a small amount of bevel cutting is required. The cross-sectional shape of the dicing blade that has not been used for bevel cutting is less likely to be deformed as compared to the dicing blade that has been used for bevel cutting. Therefore, it is possible to use the dicing blade for a long period of time and to reduce a manufacturing cost.

In the method for manufacturing a semiconductor device described above, a wet etching solution used in the step (c) is a mixed solution of hydrofluoric acid, nitric acid, sulfuric acid, phosphoric acid, and water.

According to the method for manufacturing a semiconductor device described above according to an aspect of the invention, the inner surface of the groove is wet-etched using the mixed solution of hydrofluoric acid, nitric acid, sulfuric acid, phosphoric acid, and water as the wet etching solution, which makes it possible to reduce the surface roughness of the inner surface of the groove to 0.1 μm or less.

In the method for manufacturing a semiconductor device described above, the insulating film in the step (a) is a silicon oxide film formed by a thermal oxidation method.

According to the method for manufacturing a semiconductor device described above according to an aspect of the invention, the silicon oxide film formed by the thermal oxidation method is used as the insulating film in the step (a), which makes it possible to easily form the insulating films on the upper and lower surfaces of the silicon wafer.

In the method for manufacturing a semiconductor device described above, the lead-free glass layer in the step (e) is formed on the silicon oxide film on the inner surface of the groove by an electrophoretic deposition method.

According to the method for manufacturing a semiconductor device described above according to an aspect of the invention, the silicon oxide film on the inner surface of the groove has a thickness of 100 nm or less, which makes it possible to easily form the lead-free glass layer on the silicon oxide film using the electrophoretic deposition method.

In the method for manufacturing a semiconductor device described above, the lead-free glass layer in the step (e) is formed on the silicon oxide film on the inner surface of the groove by a printing method.

According to another aspect, there is provided a mesa diode including:
a first-conductivity-type semiconductor layer;
a second-conductivity-type semiconductor layer in contact with the first-conductivity-type semiconductor layer;
a silicon oxide film formed on a side surface of the second-conductivity-type semiconductor layer, an end portion of an interface between the second-conductivity-type semiconductor layer and the first-conductivity-type semiconductor layer, and a portion of a side surface of the first-conductivity-type semiconductor layer; and
a lead-free glass layer disposed on the silicon oxide film,
   in which a surface roughness of each of the side surfaces of the second-conductivity-type semiconductor layer, the end portion of the interface between the second-conductivity-type semiconductor layer and the first-conductivity-type semiconductor layer, and the portion of the side surface of the first-conductivity-type semiconductor layer is equal to or less than 0.1 μm.

According to the mesa diode described above according to an aspect of the invention, the surface roughness of each of the side surface of the second-conductivity-type semiconductor layer, the end portion of the interface between the second-conductivity-type semiconductor layer and the first-conductivity-type semiconductor layer, and the portion of the side surface of the first-conductivity-type semiconductor layer is equal to or less than 0.1 μm. The silicon oxide film formed on the side surface of the second-conductivity-type semiconductor layer, the end portion of the interface between the second-conductivity-type semiconductor layer and the first-conductivity-type semiconductor layer, and the portion of the side surface of the first-conductivity-type semiconductor layer whose surface roughness is equal to or less than 0.1 μm, and the lead-free glass layer is disposed on the silicon oxide film. That is, since the lead-free glass layer is formed on the surface with a surface roughness of 0.1 μm or less, the mesa diode can have high withstand voltage characteristics. According to another embodiment, there is provided a mesa diode including:
a first-conductivity-type semiconductor layer;
a second-conductivity-type semiconductor layer in contact with the first-conductivity-type semiconductor layer;
a silicon oxide film formed on a side surface of the first-conductivity-type semiconductor layer, an end portion of an interface between the first-conductivity-type semiconductor layer and the second-conductivity-type semiconductor layer, and a portion of a side surface of the second-conductivity-type semiconductor layer; and
a lead-free glass layer disposed on the silicon oxide film,
   in which a surface roughness of each of the side surfaces of the first-conductivity-type semiconductor layer, the end portion of the interface between the first-conductivity-type semiconductor layer and the second-conductivity-type semiconductor layer, and the portion of the side surface of the second-conductivity-type semiconductor layer is equal to or less than 0.1 μm.

In the mesa diode described above, a thickness of the silicon oxide film is equal to or less than 100 nm.

According to various aspects of the invention, it is possible to provide a mesa diode manufactured using lead-free glass without using a photolithography step and a large amount of chemicals and a method for manufacturing a semiconductor device.

### BRIEF DESCRIPTION OF DRAWINGS

FIGS. 1A to 1C are cross-sectional views illustrating a method for manufacturing a semiconductor device according to an aspect of the invention;

FIGS. 2A to 2C are cross-sectional views illustrating a method for manufacturing a semiconductor device according to an aspect of the invention;

FIG. 3A is an optical microscope photograph of an inner surface of a groove 13;

FIG. 3B is a photograph illustrating a cross section of the groove 13;

FIG. 3C is a graph illustrating characteristics of a lead-free glass layer and illustrating device characteristics of sample B according to an example illustrated in Table 1; and

FIG. 3D is a graph illustrating device characteristics of sample A according to a comparative example illustrated in Table 1.

### MODE(S) FOR CARRYING OUT THE INVENTION

Hereinafter, embodiments of the invention will be described in detail with reference to the drawings. However, the invention is not limited to the following description, and it will be easily understood by those skilled in the art that the form and details of the invention can be changed in various ways without departing from the gist and scope of the invention. Therefore, the invention should not be construed as being limited to the content described in the following embodiments.

### First Embodiment

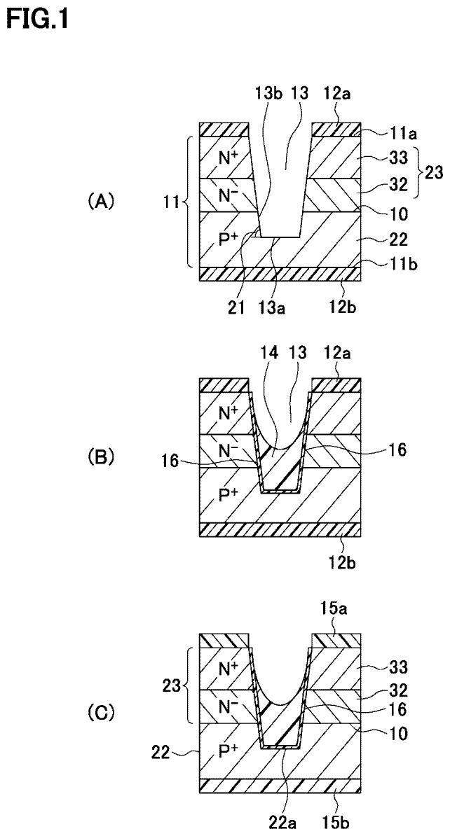

FIGS. 1A to 1C are cross-sectional views illustrating a method for manufacturing a semiconductor device according to an aspect of the invention.

The method for manufacturing a semiconductor device described in [1] according to an aspect of the invention includes a step (a) of forming insulating films 12a and 12b on an upper surface 11a and a lower surface 11b of a silicon wafer 11 having a PN junction 10, as illustrated in FIG. 1A. The insulating films 12a and 12b may be silicon oxide films formed by a thermal oxidation method. The use of the silicon oxide films formed by the thermal oxidation method as the insulating films 12a and 12b makes it possible to easily form the insulating films 12a and 12b on the upper surface 11a and the lower surface 11b of the silicon wafer 11.

In addition, before the step (a), for example, boron and phosphorus may be simultaneously diffused from both surfaces of the N⁻-type silicon wafer to the entire surface. That is, boron is diffused from the entire lower surface of the N⁻-type silicon wafer 11 at the same time as phosphorus is diffused from the entire upper surface of the N⁻-type silicon wafer 11. As a result, a P⁺-type semiconductor layer (also referred to as a first-conductivity-type semiconductor layer) 22, an N⁻-type semiconductor layer 32, and an N⁺-type semiconductor layer 33 are formed on the N⁻-type silicon wafer 11 in this order from the lower surface side. In addition, the N⁻-type semiconductor layer 32 and the N⁺-type semiconductor layer 33 are collectively referred to as a second-conductivity-type semiconductor layer 23. That is, the N⁺-type semiconductor layer 33 has a higher impurity concentration than the N⁺-type semiconductor layer 32, and the N⁺-type semiconductor layer 33 is in contact with the N⁻-type semiconductor layer 32. The N⁻-type semiconductor layer 32 is joined to the P⁺-type semiconductor layer 22, and the PN junction 10 is formed at an interface where the P⁺-type semiconductor layer 22 and the N⁻-type semiconductor layer 32 are joined.

In addition, in this embodiment, the N⁺-type semiconductor layer 33 is formed on the upper surface side, and the P⁺-type semiconductor layer 22 is formed on the lower surface side. However, the P⁺-type semiconductor layer may be formed on the upper surface side, and the N⁺-type semiconductor layer 33 may be formed on the lower surface side.

Then, the upper surface of the silicon wafer 11 is cut with a dicing blade to form a groove 13 with a depth exceeding the PN junction 10 (step (b)).

Specifically, the groove 13 having a depth from the upper surface of the silicon wafer 11 on the side of the N⁺-type semiconductor layer 33 to the middle of the P⁺-type semiconductor layer 22 through the N⁻-type semiconductor layer 32 is formed in the silicon wafer 11 by cutting with the dicing blade (not illustrated).

An angle 21 formed between a bottom surface 13a and a side surface 13b of the groove 13 in a cross section of the groove 13 having the above-described mesa structure is preferably equal to or greater than 60° and equal to or less than 90° and more preferably equal to or greater than 76° and equal to or less than 90°. When the angle 21 is 90° or close to 90° as described above, it is not necessary to perform bevel cutting with the dicing blade, or only a small amount of bevel cutting is required. The cross-sectional shape of the dicing blade that has not been used for bevel cutting is less likely to be deformed as compared to the dicing blade that has been used for bevel cutting. Therefore, it is possible to use the dicing blade for a long period of time and to reduce a manufacturing cost.

Then, an inner surface of the groove 13 formed by the above-mentioned dicing is wet-etched to reduce a surface roughness Ra of the inner surface of the groove 13 to 0.1 μm or less (step (c)). A wet etching solution may be a mixed solution of hydrofluoric acid, nitric acid, sulfuric acid, phosphoric acid, and water. When the inner surface of the groove 13 is wet-etched using the wet etching solution which is the mixed solution, it is possible to easily flatten the surface roughness Ra of the inner surface of the groove 13 to 0.1 μm or less.

Then, as illustrated in FIG. 1B, a silicon oxide film 16 is formed on the inner surface of the groove 13 (step (d)). The silicon oxide film 16 may be, for example, a thermal oxide film. In addition, a thickness of the silicon oxide film 16 may be equal to or less than 100 nm, and it is preferable that a lower limit of the thickness of the silicon oxide film 16 is 5 nm. This makes it possible to form a lead-free glass layer 14, which will be described below, using an electrophoretic deposition method. In addition, when the lead-free glass layer 14 is formed by a printing method, there is no limit to the thickness of the silicon oxide film 16, and it is also possible to use the silicon oxide film 16 with a thickness greater than 100 nm.

Then, the lead-free glass layer 14 is formed on the silicon oxide film 16 on the inner surface of the groove 13 (step (e)).

Specifically, the following two methods are given as examples of a method for forming the lead-free glass layer 14.

In a first method, the lead-free glass layer 14 is formed on the silicon oxide film 16 on the inner surface of the groove 13 by the electrophoretic deposition method. Specifically, a layer that is made of a glass composition for protecting a semiconductor junction is formed on the inner surface of the groove 13 and on the surface of the silicon wafer 11 in the vicinity of the inner surface of the groove 13 by the electrophoretic deposition method, and the layer made of the glass composition for protecting a semiconductor junction is baked to form the lead-free glass layer 14 for passivation with high chemical resistance (see FIG. 1B). Therefore, an exposed portion of the PN junction in the groove 13 is directly covered with the lead-free glass layer 14. In addition, the glass composition for protecting a semiconductor junction contains at least SiO₂, B₂O₃, Al₂O₃, ZnO, oxides of all alkaline earth metals among Cao, MgO, and Bao, and a nickel oxide and does not substantially contain Pb, As, Sb, Li, Na and K. Further, in this case, when the silicon oxide film 16 on the inner surface of the groove 13 has a thickness of 100 nm or less, the lead-free glass layer 14 can be easily formed on the silicon oxide film 16 by the electrophoretic deposition method.

In a second method, the lead-free glass layer 14 is formed on the silicon oxide film 16 on the inner surface of the groove 13 by the printing method. Specifically, a glass paste is applied onto the inner surface of the groove 13 by the printing method, and a baking process is performed on the glass paste to form the lead-free glass layer 14. The lead-free glass layer 14 functions as a passivation layer.

Then, the insulating films 12a and 12b are removed (step (f)). Specifically, the insulating films 12a and 12b on the upper and lower surfaces of the silicon wafer 11 are removed by wet etching with a chemical (buffered hydrofluoric acid) or by a mechanical process (for example, sandblasting). As a result, front and back electrode formation surfaces of the silicon wafer 11 are exposed.

Then, metal films 15a and 15b are formed on the upper surface 11a and the lower surface 11b of the silicon wafer 11 (step (g)).

Specifically, Ni-plated layers as the metal films 15a and 15b are formed on the upper and lower surfaces of the silicon wafer 11. As a result, the Ni-plated layer is formed on the entire lower surface of the silicon wafer 11, and a plurality of first electrode layers 15a which are the Ni plated layers are formed on the upper surface of the silicon wafer 11 (see FIG. 1C). Further, in this embodiment, the metal films 15a and 15b are formed by plating. However, the metal films 15a and 15b may be formed by a vapor deposition method or a sputtering method.

Then, the lead-free glass layer 14 and the silicon wafer 11 are cut along the center of the bottom surface 13a of the groove 13 (step (h)).

According to this embodiment, when the upper surface 11a of the silicon wafer 11 having the PN junction 10 is cut by the dicing blade to form the groove 13 having a depth exceeding the PN junction 10, the inner surface of the groove 13 becomes a rough surface having irregularities. Therefore, in the step (c), the inner surface of the groove 13 is wet-etched to reduce the surface roughness Ra of the inner surface of the groove 13 to 0.1 μm or less. Then, the silicon oxide film 16 is formed on the inner surface of the groove 13, and the lead-free glass layer 14 is formed as a passivation on the silicon oxide film 16 on the inner surface of the groove 13. Since cutting with the dicing blade is used while the lead-free glass layer 14 is used, it is possible to manufacture a semiconductor device without using a photolithography step and a large amount of chemicals. Furthermore, since the lead-free glass layer 14 reduces the surface roughness Ra of the inner surface of the groove 13 to 0.1 μm or less, the semiconductor device can have high withstand voltage characteristics.

Further, according to this embodiment, it is possible to manufacture a semiconductor device without using a photographic process using a photolithography technique and a large amount of chemicals. Therefore, it is possible to significantly reduce the manufacturing cost. In addition, since the lead-free glass layer 14 is used as a passivation, it is possible to respond to regulations on lead in glass by the European RoHS regulation, which contributes to environmental protection.

### Second Embodiment

The mesa diode described above according to an aspect of the invention will be described. This mesa diode is a mesa diode obtained by cutting, into a chip, the lead-free glass layer 14 and the silicon wafer 11 along the center of the bottom surface 13a of the groove 13 in the step (h) illustrated in FIG. 1C in the first embodiment.

As illustrated in FIG. 1C, this mesa diode has the first-conductivity-type semiconductor layer (P⁺-type semiconductor layer) 22 and the second-conductivity-type semiconductor layer 23 that is in contact with the first-conductivity-type semiconductor layer 22. Specifically, the N⁻-type semiconductor layer 32 is formed on the P⁺-type semiconductor layer 22, and the N⁺-type semiconductor layer 33 is formed on the N⁻-type semiconductor layer 32.

The silicon oxide film 16 is formed on the side surface of the second-conductivity-type semiconductor layer (for example, the N⁻-type semiconductor layer 32 and the N⁺-type semiconductor layer 33 on the N⁻-type semiconductor layer 32) 23, an end portion of the interface (PN junction surface) 10 between the second-conductivity-type semiconductor layer 23 and the first-conductivity-type semiconductor layer (for example, the P⁺-type semiconductor layer) 22, and a portion of the side surface of the first-conductivity-type semiconductor layer (P⁺-type semiconductor layer) 22. The lead-free glass layer 14 is disposed on the silicon oxide film 16.

The surface roughness Ra of each of the side surfaces of the second-conductivity-type semiconductor layer 23 (for example, the N⁻-type semiconductor layer 32 and the N⁺-type semiconductor layer 33 on the N⁻-type semiconductor layer 32), the end portion of the interface (PN junction surface) 10 between the second-conductivity-type semiconductor layer 23 and the first-conductivity-type semiconductor layer (P⁺-type semiconductor layer) 22, and the portion of the side surface of the first-conductivity-type semiconductor layer (P⁺-type semiconductor layer) 22 is equal to or less than 0.1 μm.

According to this embodiment, the surface roughness Ra of each of the portion of the side surface of the P⁺-type semiconductor layer 22 and the side surfaces of the N⁻-type semiconductor layer 32 and the N⁺-type semiconductor layer 33 is set to 0.1 μm or less, and the silicon oxide film 16 is formed on the portion of the side surface of the P⁺-type semiconductor layer 22, the side surfaces of the N⁻-type semiconductor layer 32 and the N⁺-type semiconductor layer 33, and the end portion of the interface (PN junction surface) 10 whose surface roughness Ra is equal to or less than 0.1 μm. The lead-free glass layer 14 is disposed on the silicon oxide film 16. That is, since the lead-free glass layer 14 is formed on the surface whose surface roughness Ra is equal to or less than 0.1 μm, the mesa diode can have high withstand voltage characteristics.

In addition, the thickness of the silicon oxide film 16 may be equal to or less than 100 nm. In this case, as described in the first embodiment, the lead-free glass layer 14 can be formed by the electrophoretic deposition method.

### Third Embodiment

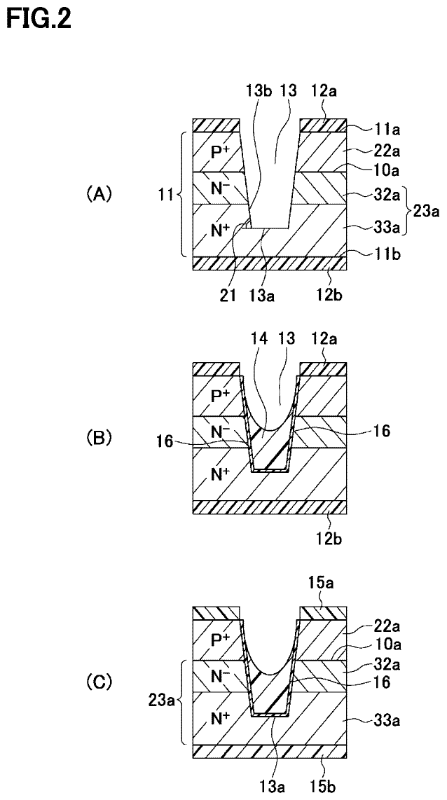

FIGS. 2A to 2C are cross-sectional views illustrating a method for manufacturing a semiconductor device according to an aspect of the invention. In addition, FIG. 2 illustrates an embodiment obtained by reversing the first conductivity type and the second conductivity type illustrated in FIG. 1. Specifically, a first-conductivity-type semiconductor layer 22a is a P⁺-type semiconductor layer, a second-conductivity-type semiconductor layer 23a includes an N⁻-type semiconductor layer 32a and an N⁺-type semiconductor layer 33a on the N⁻-type semiconductor layer 32a, and the upper surface 11a and the lower surface 11b of the silicon wafer 11 are reversed. The second embodiment is the same as the first embodiment except for this. Therefore, the same portions are denoted by the same reference numerals, and a description of the same portions will be omitted.

The method for manufacturing a semiconductor device described above according to an aspect of the invention includes a step (a) of forming the insulating films 12a and 12b on the upper surface 11a and the lower surface 11b of the silicon wafer 11 having a PN junction 10a as illustrated in FIG. 2A.

In addition, before the step (a), boron and phosphorus may be simultaneously diffused from both surfaces of the N⁻-type silicon wafer to the entire surface. That is, boron is diffused from the entire upper surface of the N⁻-type silicon wafer 11 at the same time as phosphorus is diffused from the entire lower surface of the N⁻-type silicon wafer 11. As a result, the P⁺-type semiconductor layer (also referred to as a first-conductivity-type semiconductor layer) 22a, the N⁻-type semiconductor layer 32a, and the N⁺-type semiconductor layer 33a are formed on the N⁻-type silicon wafer 11 in this order from the upper surface side. In addition, the N⁻-type semiconductor layer 32a and the N⁺-type semiconductor layer 33a are collectively referred to as a second-conductivity-type semiconductor layer 23a. The N⁻-type semiconductor layer 32a is joined to the P⁺-type semiconductor layer 22a, and the PN junction 10a is formed at an interface where the P⁺-type semiconductor layer 22a and the N⁻-type semiconductor layer 32a are joined.

Then, the upper surface of the silicon wafer 11 is cut with the dicing blade to form the groove 13 with a depth exceeding the PN junction 10a (step (b)).

Specifically, the groove 13 having a depth from the upper surface of the silicon wafer 11 on the side of the P⁺-type semiconductor layer 22a to the middle of the N⁺-type semiconductor layer 33a through the N⁻-type semiconductor layer 32a is formed in the silicon wafer 11 by cutting with the dicing blade (not illustrated).

Then, the inner surface of the groove 13 is wet-etched to reduce the surface roughness Ra of the inner surface of the groove 13 to 0.1 μm or less (step (c)). A wet etching solution may be a mixed solution of hydrofluoric acid, nitric acid, sulfuric acid, phosphoric acid, and water. When the inner surface of the groove 13 is wet-etched using the wet etching solution which is the mixed solution, it is possible to easily flatten the surface roughness Ra of the inner surface of the groove 13 to 0.1 μm or less.

In this embodiment, it is possible to obtain the same effects as those in the first embodiment.

### Fourth Embodiment

The mesa diode described above according to an aspect of the invention will be described. This mesa diode is a mesa diode obtained by cutting, into a chip, the lead-free glass layer 14 and the silicon wafer 11 along the center of the bottom surface 13a of the groove 13 using the process illustrated in FIG. 2C in the third embodiment. As described in the third embodiment, in FIG. 2C, the same portions as those in FIG. 1C are denoted by the same reference numerals, and a description of the same portion will be omitted.

As illustrated in FIG. 2C, this mesa diode has a first-conductivity-type semiconductor layer (P⁺-type semiconductor layer) 22a and a second-conductivity-type semiconductor layer 23a that is in contact with the first-conductivity-type semiconductor layer 22a. Specifically, an N⁻-type semiconductor layer 32a is formed below the P⁺-type semiconductor layer 22a, and an N⁺-type semiconductor layer 33a is formed below the N⁻-type semiconductor layer 32a.

A silicon oxide film 16 is formed on a side surface of the first-conductivity-type semiconductor layer (P⁺-type semiconductor layer) 22a, an end portion of an interface (PN junction surface) 10a between the first-conductivity-type semiconductor layer (for example, the P⁺-type semiconductor layer) 22a and the second-conductivity-type semiconductor layer 23a, and a portion of a side surface of the second-conductivity-type semiconductor layer (for example, the N⁻-type semiconductor layer 32a and the N⁺-type semiconductor layer 33a on the N⁻-type semiconductor layer 32a) 23a.

The surface roughness Ra of each of the side surfaces of the first-conductivity-type semiconductor layer (P⁺-type semiconductor layer) 22a, the end portion of the interface (PN junction surface) 10a between the first-conductivity-type semiconductor layer (for example, the P⁺-type semiconductor layer) 22a and the second-conductivity-type semiconductor layer 23a, and the portion of the side surface of the second-conductivity-type semiconductor layer (for example, the N⁻-type semiconductor layer 32a and the N⁺-type semiconductor layer 33a on the N⁻-type semiconductor layer 32a) 23a is equal to or less than 0.1 μm.

In this embodiment, it is also possible to obtain the same effects as those in the first embodiment.

### Examples

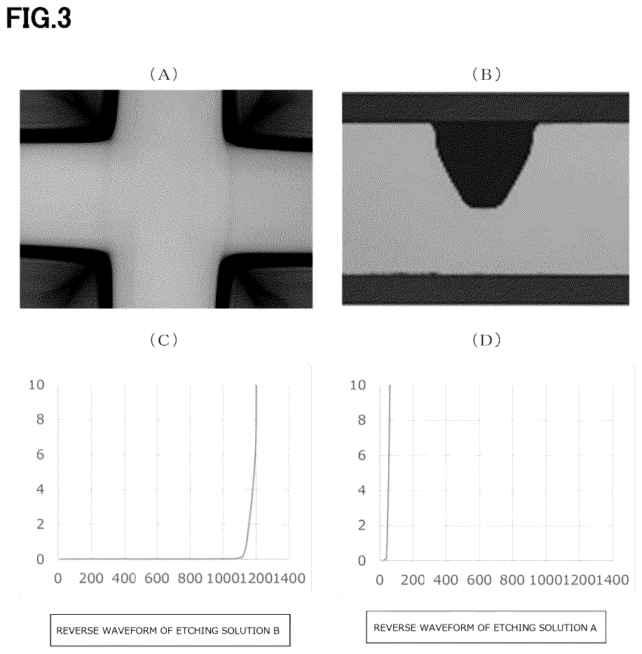

Two samples of sample A according to a comparative example and sample B according to an example were created by changing an etching solution for wet-etching the inner surface of the groove 13 illustrated in FIGS. 3A and 3B to adjust the surface roughness Ra of the inner surface of the groove 13 as illustrated in Table 1. Measurement results of the surface roughness Ra and device characteristics of these samples are illustrated in Table 1. In addition, these samples (mesa diodes) were manufactured by the same manufacturing method as that in the third embodiment except that the etching solution was different.

TABLE 1

Area analysis (30 × 30 μm)

| Etching solution | A | B |
|---|---|---|
| Ra | 0.466 | 0.081 |
| Device characteristics | X | ◯ |

Etching solution A is a mixed solution of hydrofluoric acid, nitric acid, acetic acid, and water.

Etching solution B is a mixed solution of hydrofluoric acid, nitric acid, sulfuric acid, phosphoric acid, and water.

A method for measuring the surface roughness is as follows.
Device used: KEYENCE laser microscope
   Magnification: ×100
Measurement value: Ra (arithmetic average roughness)
   Ra: Arithmetic average roughness (Za) indicates the average of the absolute values of Z(x) at a standard length. When a profile curve is a roughness curve, Ra is referred to as a conventional term “arithmetic average roughness”. When the profile curve is a waviness curve, Wa is referred to as an “arithmetic average waviness”. Even when there are large irregularities such as scratches, the numerical value is less likely to be affected, and it is possible to measure a relatively stable surface roughness.

A method for evaluating the device characteristics illustrated in Table 1 is as follows.

After an etching process, reverse characteristics of a device (diode) subjected to passivation formation and electrode formation were evaluated. In the evaluation, a reverse voltage VR-1 kV was used as a threshold value.

When the device characteristics are “O”, it is possible to ensure a reverse voltage of 1 kV or more (see FIG. 3C).

When the device characteristics are “X”, it is impossible to ensure a reverse voltage of 1 kV or more (see FIG. 3D).

As illustrated in Table 1, when the surface roughness Ra is equal to or less than 0.1 μm, it is possible to obtain good device characteristics.

FIG. 3A is a planar photograph of the silicon wafer after the inside of the groove of sample B illustrated in Table 1 is etched, and FIG. 3B is a cross-sectional photograph of the silicon wafer after the inside of the groove of sample B illustrated in Table 1 is etched. FIG. 3C is a graph illustrating the device characteristics of sample B according to the example illustrated in Table 1. In the graph, the vertical axis is a reverse current, and the horizontal axis is a reverse voltage. FIG. 3D is a graph illustrating the device characteristics of sample A according to the comparative example illustrated in Table 1. In the graph, the vertical axis is the reverse current, and the horizontal axis is the reverse voltage.

As can be seen from FIG. 3C, even when a lead-free glass layer is used as a passivation, the withstand voltage is approximately 1200 V.

Furthermore, as can be seen from FIG. 3B, there are no dicing marks at the bottom of the groove, and the shape of the groove has not changed significantly.

### EXPLANATIONS OF LETTERS OR NUMERALS

10, 10a PN JUNCTION (INTERFACE BETWEEN SECOND-CONDUCTIVITY-TYPE SEMICONDUCTOR LAYER AND FIRST-CONDUCTIVITY-TYPE SEMICONDUCTOR LAYER)
11 SILICON WAFER
11a UPPER SURFACE OF SILICON WAFER
11b LOWER SURFACE OF SILICON WAFER
12a, 12b INSULATING FILM (SILICON OXIDE FILM)
13 GROOVE
13a BOTTOM SURFACE OF GROOVE
13b SIDE SURFACE OF GROOVE
14 LEAD-FREE GLASS LAYER
15a, 15b METAL FILM
16 SILICON OXIDE FILM
21 ANGLE FORMED BETWEEN BOTTOM SURFACE AND SIDE SURFACE OF GROOVE
22, 22a FIRST-CONDUCTIVITY-TYPE SEMICONDUCTOR LAYER (P⁺-TYPE SEMICONDUCTOR LAYER)
23, 23a SECOND-CONDUCTIVITY-TYPE SEMICONDUCTOR LAYER
Ra SURFACE ROUGHNESS

1. A method for manufacturing a semiconductor device, comprising:
forming insulating films on upper and lower surfaces of a silicon wafer having a PN junction;
cutting the upper surface of the silicon wafer with a dicing blade to form a groove with a depth exceeding the PN junction;
wet-etching an inner surface of the groove to reduce a surface roughness of the inner surface of the groove to 0.1 μm or less;
forming a silicon oxide film on the inner surface of the groove;
forming a lead-free glass layer on the silicon oxide film on the inner surface of the groove;
removing the insulating films;
forming metal films on the upper and lower surfaces of the silicon wafer; and
cutting the lead-free glass layer and the silicon wafer along a center of a bottom surface of the groove.

2. The method for manufacturing a semiconductor device according to claim 1,
wherein the formed silicon oxide film is an oxide film having a thickness of 100 nm or less.

3. The method for manufacturing a semiconductor device according to claim 1,
wherein an angle formed between the bottom surface and a side surface of the groove in a cross section of the formed groove is equal to or greater than 60° and equal to or less than 90°.

4. The method for manufacturing a semiconductor device according to claim 1,
wherein the wet etching includes a wet etching solution comprising a mixed solution of hydrofluoric acid, nitric acid, sulfuric acid, phosphoric acid, and water.

5. The method for manufacturing a semiconductor device according to claim 1,
wherein the formed insulating film comprises a silicon oxide film formed by a thermal oxidation method.

6. The method for manufacturing a semiconductor device according to claim 2,
wherein the lead-free glass layer is formed on the silicon oxide film on the inner surface of the groove by an electrophoretic deposition method.

7. The method for manufacturing a semiconductor device according to claim 1,
wherein the lead-free glass layer is formed on the silicon oxide film on the inner surface of the groove by a printing method.

8. A mesa diode comprising:
a first-conductivity-type semiconductor layer;
a second-conductivity-type semiconductor layer in contact with the first-conductivity-type semiconductor layer;
a silicon oxide film formed on a side surface of the second-conductivity-type semiconductor layer, an end portion of an interface between the second-conductivity-type semiconductor layer and the first-conductivity-type semiconductor layer, and a portion of a side surface of the first-conductivity-type semiconductor layer; and
a lead-free glass layer disposed on the silicon oxide film,
wherein a surface roughness of each of the side surfaces of the second-conductivity-type semiconductor layer, the end portion of the interface between the second-conductivity-type semiconductor layer and the first-conductivity-type semiconductor layer, and the portion of the side surface of the first-conductivity-type semiconductor layer is equal to or less than 0.1 μm.

9. A mesa diode comprising:
a first-conductivity-type semiconductor layer;
a second-conductivity-type semiconductor layer that is in contact with the first-conductivity-type semiconductor layer;
a silicon oxide film formed on a side surface of the first-conductivity-type semiconductor layer, an end portion of an interface between the first-conductivity-type semiconductor layer and the second-conductivity-type semiconductor layer, and a portion of a side surface of the second-conductivity-type semiconductor layer; and
a lead-free glass layer disposed on the silicon oxide film,
wherein a surface roughness of each of the side surfaces of the first-conductivity-type semiconductor layer, the end portion of the interface between the first-conductivity-type semiconductor layer and the second-conductivity-type semiconductor layer, and the portion of the side surface of the second-conductivity-type semiconductor layer is equal to or less than 0.1 μm.

10. The mesa diode according to claim 8,
wherein a thickness of the silicon oxide film is equal to or less than 100 nm.

11. The mesa diode according to claim 9,
Wherein a thickness of the silicon oxide film is equal to or less than 100 nm.
